(19) United States
(12) Patent Application Publication
(10) Pub. No.: US 2010/0151676 A1
(43) Pub. Date: Jun. 17, 2010

(54) DENSIFICATION PROCESS FOR TITANIUM NITRIDE LAYER FOR SUBMICRON APPLICATIONS

(75) Inventors: Alan Alexander Ritchie, Pleasanton, CA (US); Mohd Fadzil Anwar Hassan, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/335,582

(22) Filed: Dec. 16, 2008

(51) Int. Cl. H01L 21/441; H01L 21/443

(52) U.S. Cl. 438/660; 438/681; 257/E21.477; 257/E21.478

(57) ABSTRACT

Embodiments of the present invention provide methods of forming and densifying a titanium nitride barrier layer. The densification process is performed at a relatively low RF plasma power and high nitrogen to hydrogen ratio so as to provide a substantially titanium rich titanium nitride barrier layer. In one embodiment, a method for forming a titanium nitride barrier layer on a substrate includes depositing a titanium nitride layer on the substrate by a metal-organic chemical vapor deposition process, and performing a plasma treatment process on the deposited titanium nitride layer, wherein the plasma treatment process operates to densify the deposited titanium nitride layer, resulting in a densified titanium nitride layer, wherein the plasma treatment process further comprises supplying a plasma gas mixture containing a nitrogen gas to hydrogen gas ratio between about 20:1 and about 3:1, and applying less than about 500 Watts RF power to the plasma gas mixture.

### BACKGROUND OF THE INVENTION

1. Field of the Invention

Embodiments of the invention generally relate to a fabrication process for forming a barrier layer on a substrate, and more particularly, to a densification process for a titanium nitride barrier material on semiconductor substrates.

2. Description of the Related Art

Reliably producing submicron and smaller features is one of the key technologies for the next generation of very large scale integration (VLSI) and ultra large scale integration (ULSI) of semiconductor devices. However, as the fringes of circuit technology are pressed, the shrinking dimensions of interconnects in VLSI and ULSI technology have placed additional demands on the processing capabilities. The multilevel interconnects that lie at the heart of this technology require precise processing of high aspect ratio features, such as vias and other interconnects. Reliable formation of these interconnects is very important to VLSI and ULSI success and to the continued effort to increase circuit density and quality of individual substrates.

As circuit densities increase for next generation devices, the widths of interconnects, such as vias, trenches, contacts, gate structures and other features, as well as the dielectric materials therebetween, decrease to 45 nm and 32 nm dimensions, whereas the thickness of the dielectric layers remain substantially constant, with the result of increasing the aspect ratios of the features. Many traditional deposition processes have difficulty filling submicron structures where the aspect ratio exceeds 4:1. Therefore, there is a great amount of ongoing effort being directed at the formation of substantially void-free and seam-free and conformal submicron features having high aspect ratios.

In the manufacture of integrated circuits, a titanium/titanium nitride stack, such as a titanium nitride layer over a titanium layer, is often used as a liner barrier. The titanium/titanium nitride stack may be used to provide contacts to the source and drain of a transistor. The titanium nitride layer may be used as a barrier layer to inhibit the diffusion of metals into regions underlying the barrier layer in a contact or back end interconnection structure. A conductive metal layer, such as a copper-containing layer, aluminum layer or a tungsten-containing layer, is usually deposited over the titanium nitride layer.

The titanium layer or the titanium nitride layer may be formed by a chemical vapor deposition (CVD) process, an atomic layer deposition (ALD) process, and/or a physical vapor deposition (PVD) process. For example, the titanium layer may be formed by reacting titanium tetrachloride with a reducing agent during a CVD process and the titanium nitride layer may be formed by reacting titanium tetrachloride with ammonia during a CVD process. Thereafter, the conductive material may be deposited onto the substrate.

A variety of problems that eventually may lead to device failure may result from the specific process used to deposit or form the titanium nitride layer. For example, titanium nitride barrier layers deposited using a PVD process often suffer from poor step coverage, overhang, and voids formed within the via or trench when the via is less than 50 nm or having an aspect ratio greater than 4:1. Insufficient deposition on the bottom and sidewall of the vias or trenches can also result in deposition discontinuity, thereby resulting in device shorting or poor interconnection formation. Furthermore, the titanium nitride layer may have poor adhesion over the titanium layer and the subsequent metal layer disposed thereover, resulting in peeling of the titanium nitride layer from the titanium layer and the subsequent conductive metal layer.

Titanium nitride barrier layers deposited using a conventional CVD process may further experience the severe problem of the conductive metal material (e.g., Cu, W, or Al) diffusing through the barrier layer and into neighboring materials, such as dielectric materials. Often, diffusion occurs because the barrier layer is too thin or contains a barrier material that is not dense enough (e.g., too porous) to prohibit or limit the diffusing of metallic atoms. Thicker barrier layers may be used to limit or control diffusion. However, the resistance of a barrier layer increases proportional to the thickness, as does the time and cost for deposition.

Furthermore, the titanium nitride barrier layers also serve as a seed layer that provides a nucleation surface for the subsequent conductive contact material (e.g., Cu, W, or Al) to deposit on the titanium nitride barrier layers to successfully form the desired interconnection structure. However, different stoichiometric ratios of titanium to nitrogen elements in the titanium nitride barrier layer may result in different nucleation capabilities of the subsequent conductive contact material that is deposited thereover. Poor process control of the titanium nitride barrier layer may cause unreliable stoichiometric ratios of the titanium to nitrogen elements, thereby adversely affecting nucleation of the conductive contact material and resulting in poor adhesion, voids, or associated defects in the interconnection structure.

Therefore, there is a need for an improved method of forming and densifying barrier materials, particularly titanium nitride barrier material.

### SUMMARY OF THE INVENTION

Embodiments of the present invention provide methods of forming and densifying a titanium nitride barrier layer. In one embodiment, a method for forming a titanium nitride barrier layer on a substrate includes depositing a titanium nitride layer on the substrate by a metal-organic chemical vapor deposition process, and performing a plasma treatment process on the deposited titanium nitride layer, wherein the plasma treatment process operates to densify the deposited titanium nitride layer, resulting in a densified titanium nitride layer, wherein the plasma treatment process further comprises supplying a plasma gas mixture containing a nitrogen gas to hydrogen gas ratio between about 20:1 and about 3:1, and applying less than about 500 Watts RF power to the plasma gas mixture.

In another embodiment, a method for forming a titanium nitride barrier layer on a substrate includes depositing a first titanium nitride layer to a thickness of between about 10 Å and about 20 Å by a first metal-organic chemical vapor deposition process, plasma treating the first titanium nitride layer by applying less than about 500 Watts RF power to a plasma gas mixture comprising nitrogen gas and hydrogen gas, depositing a second titanium nitride layer to a thickness of between about 10 Å and about 20 Å on the first titanium nitride layer, and plasma treating the second titanium nitride layer deposited on the substrate by applying less than about 500 Watts RF power to a plasma gas mixture comprising nitrogen gas and hydrogen gas.

In yet another embodiment, a method for forming a titanium nitride barrier layer on a substrate includes providing a substrate having vias formed in an insulating layer disposed on a substrate, wherein the substrate has a titanium layer disposed on the insulating layer and filling a portion of the vias formed therein, and exposing the substrate sequentially to a titanium nitride deposition gas and to a densifying plasma to form a plurality of densified titanium nitride barrier layers, wherein each of the densified titanium nitride barrier layers have a thickness of about 20 Å or less, wherein the densifying plasma is formed by supplying a plasma gas mixture containing a nitrogen gas to hydrogen gas ratio between about 20:1 and about 3:1, and applying a less than about 500 Watts RF power to the plasma gas mixture.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a cross sectional view of a chemical vapor deposition process chamber that may be utilized to practice one embodiment of the present invention;

FIG. 2 depicts a flow chart of a process for forming and densifying a titanium nitride material as described in one embodiment herein; and

FIGS. 3A-3D depict a cross-sectional view of a substrate during processes for forming and densifying titanium nitride layers as described in embodiments herein.

### DETAILED DESCRIPTION

One embodiment of the invention provides a method of forming and densifying a titanium nitride layer on a substrate by exposing the substrate to a hydrogen and nitrogen containing light plasma. The densification process is performed at a relatively low RF plasma power and a high nitrogen to hydrogen ratio so as to provide a substantially titanium rich titanium nitride barrier layer. The titanium nitride barrier material may contain a single densified titanium nitride layer or a titanium nitride barrier stack containing two, three, or more densified titanium nitride layers. Each densified titanium nitride layers may have a thickness of about 20 Å or less. Subsequent to exposing the substrate to a hydrogen or nitrogen containing plasma process, the method provides exposing the substrate to air for a predetermined time period prior to depositing a conductive layer on the substrate. In one embodiment, the titanium nitride layer is deposited by a CVD process, a MOCVD process, an ALD process, or any other suitable chemical vapor deposition processes. In one embodiment, the densified titanium nitride layer may have a thickness within a range from about 5 Å to about 20 Å, for example, about 15 Å or less.

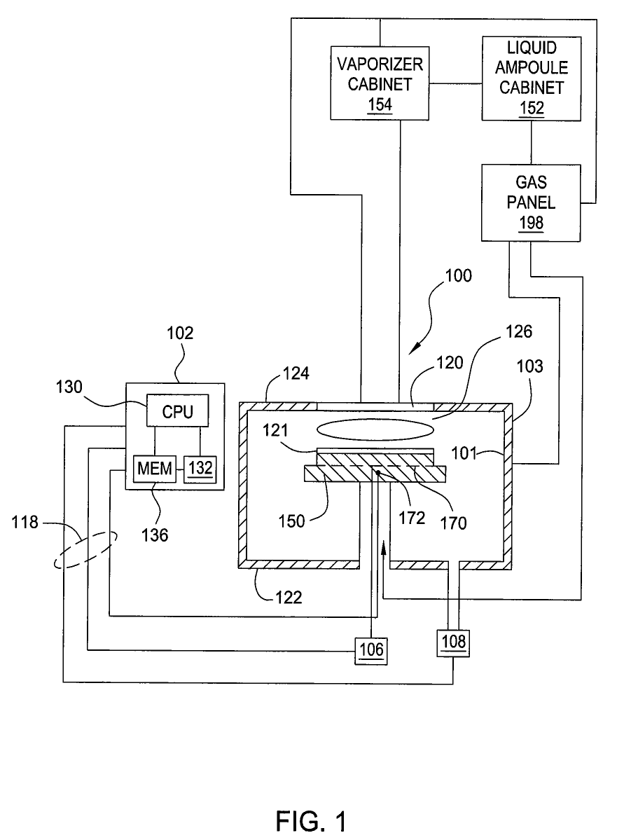

FIG. 1 depicts one embodiment of a process chamber 100 that may be used to deposit a titanium nitride layer. The process chamber 100 is configured to perform a MOCVD process for depositing a titanium nitride layer on the substrate. It is contemplated that other suitable types of process chambers, including those from other manufacturers, may also be adapted to practice the embodiments of the present invention. The processing chamber 100 includes a chamber body 103 enclosed by a lid assembly 124. The lid assembly 124, or other portion of the chamber body 100 includes a gas distributor 120 for providing process gas into the chamber 100. The chamber body 103 generally includes sidewalls 101 and a bottom wall 122 that define an interior volume 126. A support pedestal 150 is provided in the interior volume 126 of the chamber body 103. The pedestal 150 may be fabricated from aluminum, ceramic, and other suitable materials. The pedestal 150 may be moved in a vertical direction inside the chamber body 103 using a displacement mechanism (not shown).

The pedestal 150 may include an embedded heater element 170 suitable for controlling the temperature of a substrate 121 supported thereon. In one embodiment, the pedestal 150 may be resistively heated by applying an electric current from a power supply 106 to the heater element 170. In one embodiment, the heater element 170 may be made of a nickel-chromium wire encapsulated in a nickel-iron-chromium alloy (e.g., INCOLOY®) sheath tube. The electric current supplied from the power supply 106 is regulated by a controller 102 to control the heat generated by the heater element 170, thereby maintaining the substrate 121 and the pedestal 150 at a substantially constant temperature during film deposition. The supplied electric current may be adjusted to selectively control the temperature of the pedestal 150 between about 100 degrees Celsius to about 800 degrees Celsius, such as 250 degrees Celsius to about 500 degrees Celsius, for example, from about 320 degrees Celsius to about 420 degrees Celsius, for example, about 360 degrees Celsius.

A temperature sensor 172, such as a thermocouple, may be embedded in the support pedestal 150 to monitor the temperature of the pedestal 150 in a conventional manner. The measured temperature is used by the controller 102 to regulate the power supplied to the heating element 170 so that the substrate 121 is maintained at a desired temperature.

A vacuum pump 108 is coupled to a port formed in the bottom 122 of the processing chamber 100. The vacuum pump 108 is used to maintain a desired gas pressure in the processing chamber 100. The vacuum pump 108 also evacuates post-processing gases and by-products of the process from the processing chamber 100.

A gas panel 198 is connected to the gas distributor 120 through a liquid ampoule cabinet 152 and a vaporizer cabinet 154. The gas panel 198 introduces gases through the liquid ampoule cabinet 152 and the vaporizer cabinet 154 which carriers a metal precursor from the cabinets 152, 154 to the interior volume 126. One or more apertures (not shown) may be formed in the gas distributor 120 to facilitate gas flowing to the interior volume 126. The apertures may have different sizes, number, distributions, shape, design, and diameters to facilitate the flow of the various process gases for different process requirements. The gas panel 198 may also be connected to the chamber body 103, gas distributor 120, and/or to the pedestal 150 to provide different paths for supplying gases directly into the interior volume 126, such as for purge or other applications. Examples of gases that may be supplied from the gas panel include oxygen containing gas, such as, nitrogen (N₂), ammonia (NH₃), hydrogen (H₂), oxygen (O₂), N₂O, and NO, hydrazine (N₂H₄), methyl hydrazine (CH₃N₂H₃), dimethyl hydrazine ((CH₃)₂N₂H₂), tertbutylhydrazine (C₄H₉N₂H₃), phenylhydrazine (C₆H₅N₂H₃), 2,2′-azotertbutane ((CH₃)₆C₂N₂), ethylazide (C₂H₅N₃), plasmas thereof, derivatives thereof, or combinations thereof, among others.

The liquid ampoule cabinet 152 may store a metal precursor therein which provides source materials used to deposit a metal containing layer on the substrate 121 disposed on the pedestal 150. In one embodiment, the metal precursor may be in a liquid form. One suitable example of liquid precursor used herein includes an organic titanium precursor. The titanium precursor may be a metal-organic compound that includes tetrakis(dialkylamido)titanium compounds, such as tetrakis(dimethylamido)titanium (TDMAT), tetrakis(diethylamido)titanium (TDEAT), tetrakis(ethylmethylamido)titanium (TEMAT), and derivatives thereof. The substrate temperature is maintained at a desired temperature range so that the titanium containing precursor may be thermally decomposed while depositing a titanium nitride material onto the substrate surface. In one embodiment, tetrakis(dialkylamido)titanium compounds are thermally decomposed and the nitrogen of the amido ligands is incorporated as nitrogen within the titanium nitride material during a thermal MOCVD process. However, in an alternative embodiment, a nitrogen precursor may be used during a CVD process to deposit the titanium nitride barrier layers. Suitable examples of nitrogen precursor includes nitrogen (N₂), ammonia (NH₃), hydrazine (N₂H₄), methyl hydrazine (CH₃N₂H₃), dimethyl hydrazine ((CH₃)₂N₂H₂), tertbutylhydrazine (C₄H₉N₂H₃), phenylhydrazine (C₆H₅N₂H₃), 2,2′-azotertbutane ((CH₃)₆C₂N₂), ethylazide (C₂H₅N₃), plasmas thereof, derivatives thereof, or combinations thereof. The nitrogen concentration of the titanium nitride barrier layers may be increased by adding a supplemental nitrogen precursor.

In one embodiment, the gases supplied from the gas panel 130 push the liquid precursor in the ampoule cabinet 152 to the interior volume 126 of the chamber 100 through the vaporizer cabinet 154. The liquid precursor is heated and vaporized in the vaporizer cabinet 154, forming a metal containing vapor which is then injected to the interior volume 126 by the carrier gas. In one embodiment, the vaporizer cabinet 154 may vaporize the liquid precursor at a temperature between about 100 degrees Celsius and about 250 degrees Celsius.

The controller 102 is utilized to control the process sequence and regulate the gas flows from the gas panel 198, the liquid ampoule cabinet 152, and the vaporizer cabinet 154. Bi-directional communications between the controller 102 and the various components of the processing chamber 100 are handled through numerous signal cables collectively referred to as signal buses 118, some of which are illustrated in FIG. 1.

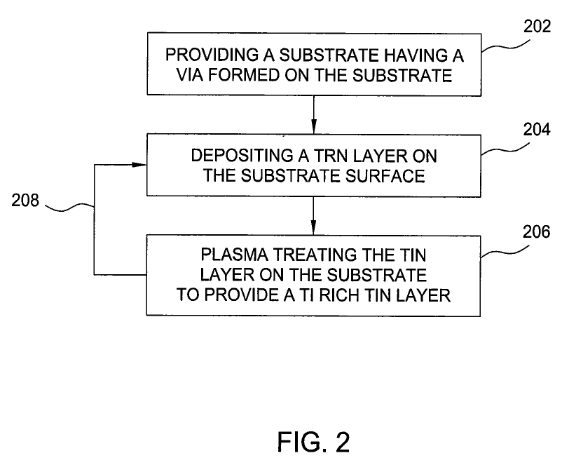

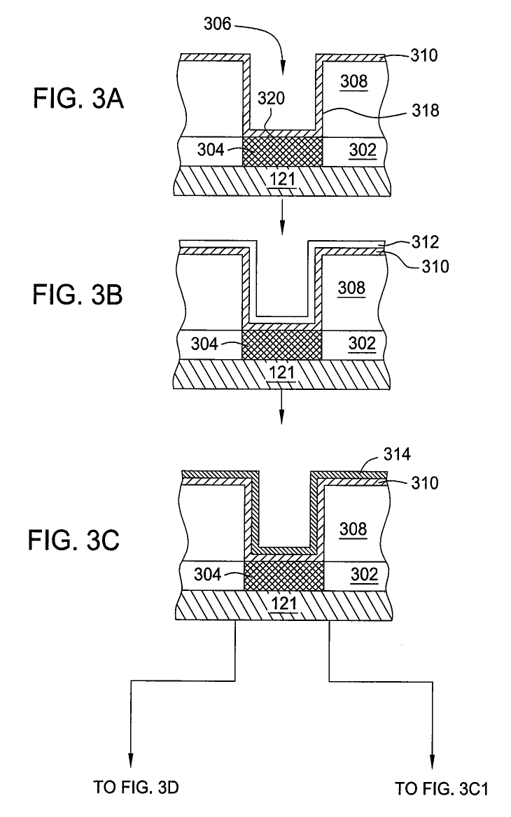

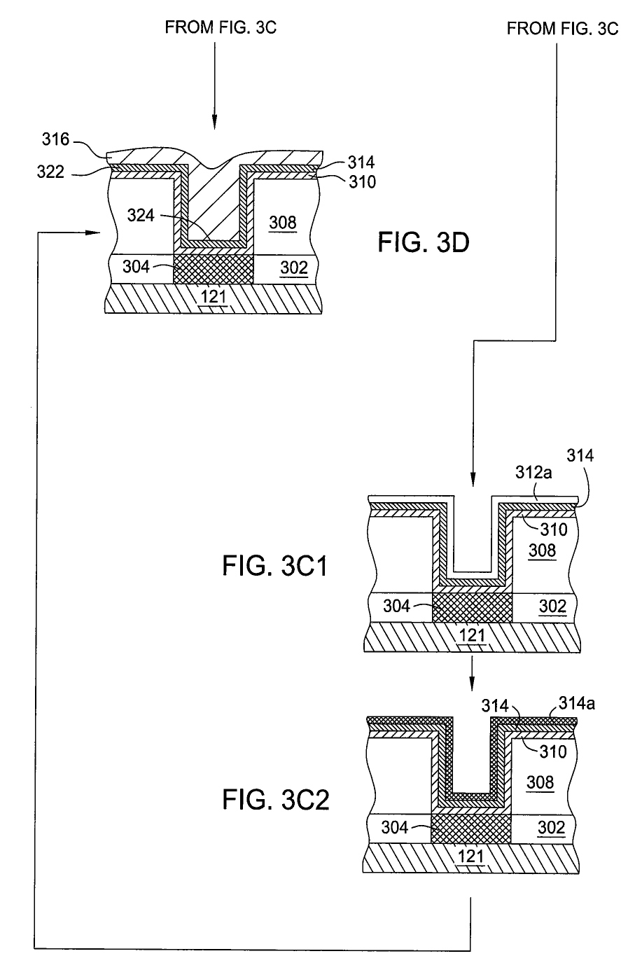

FIG. 2 depicts a process 200 of forming and densifying a titanium nitride material, such as a titanium nitride barrier layer or a titanium nitride barrier stack as described in embodiments herein. FIGS. 3A-3D depict a schematic cross-sectional view of an exemplary application of a titanium nitride material that may be formed on the substrate 121 by utilizing process 200.

The process 200 starts at step 202 by providing the substrate 121 having a desired feature formed thereon into a process chamber, such as the process chamber 100, as depicted in FIG. 1. “Substrate” or “substrate surface,” as used herein, refers to any substrate or material surface formed on a substrate upon which film processing is performed. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, quartz, and any other materials such as metals, metal nitrides, metal alloys, and other conductive materials, depending on the application. Barrier layers, metals or metal nitrides on a substrate surface may include titanium, titanium nitride, titanium silicide nitride, tungsten, tungsten nitride, tungsten silicide nitride, tantalum, tantalum nitride, or tantalum silicide nitride. Substrates may have various dimensions, such as 200 mm or 300 mm diameter wafers, as well as, rectangular or square panes. Substrates include semiconductor substrates, display substrates (e.g., LCD), solar panel substrates, and other types of substrates. Unless otherwise noted, embodiments and examples described herein are conducted on substrates with a 200 mm diameter or a 300 mm diameter. Processes of the embodiments described herein may be used to form or deposit titanium nitride materials on many substrates and surfaces. Substrates on which embodiments of the invention may be useful include, but are not limited to semiconductor wafers, such as crystalline silicon (e.g., Si<100> or Si<111>), silicon oxide, glass, quartz, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

In one embodiment, the substrate 121 may have a first insulating layer 302, as shown in FIG. 3A, formed on the substrate 121 and a second insulating layer 308 disposed over the first insulating layer 302. The first and the second insulating layers 302, 308 may be a silicon-containing layer, a silicon dioxide layer or a low-k dielectric layer. Alternatively, the first insulating layers 302 may be part of the substrate 121 so that the second insulating layer 308 may be formed directly on the substrate 121. In one embodiment, a low-k dielectric layer is an oxidized organosilane layer or an oxidized organosiloxane layer described in more detail in commonly assigned U.S. Pat. No. 6,348,725, which is incorporated by reference herein.

The second insulating layer 308 may be patterned and etched to form a via 306. In one embodiment, the via 306 may be a void, an aperture, a cavity, a hole, a trench or any suitable structures or features that a titanium nitride layer may be formed therein to form an interconnection structure.

A conductive layer 304 may be disposed in the first insulating layer 302 at a location formed in the second insulating layer 308 connecting to the via 306 to form a conductive path from the first insulating layer 302 to the second insulating layer 308. This conductive path may be utilized to form a contact structure, back end interconnection structure or other suitable metallization structures. Alternatively, the conductive layer 304 may also be as a source or drain region where the via 306 may be formed thereon to form a conductive path for a gate structure. It is contemplated that via 306 may be formed on any suitable substrates that may require a titanium nitride layer to be formed thereon for barrier/liner, metallization or any other purposes. In one embodiment, the conductive layer 304 may be copper, tungsten, aluminum, doped silicon, or other similar conductive material.

In one embodiment, an adhesion layer 310 may be formed over the second insulating layer 308 and conformally deposited over a bottom 320 and sidewalls 318 of the via 306 to promote adhesion between the second insulating layer 308 and the layer subsequently to be deposited thereon. The adhesion layer 310 may be a metallic material deposited by vapor deposition processes, such as PVD, ALD, or CVD processes. The adhesion layer 310 may be formed across the entire exposed surfaces of substrate 121. The adhesion layer 310 may contain titanium, tantalum, tungsten, ruthenium, cobalt, silicides thereof, alloys thereof, or combinations thereof. In one example, the adhesion layer 310 is a metallic titanium layer deposited by a PVD process. In another example, the adhesion layer 310 is a metallic titanium layer deposited by an ALD process. In some embodiments, the adhesion layer 310 may be eliminated and the subsequent to-be-deposited layer may be directly deposited over the second insulating layer 308. In one embodiment, the adhesion layer 310 may have a thickness between about 10 Å and about 150 Å.

In step 204, a titanium nitride layer 312 is deposited over the layer 310 on the substrate 121 over the via 306, as depicted in FIG. 3B. The titanium nitride layer 312 may completely cover the adhesion layer 310 or any other exposed surface of substrate 121, such as lower first insulating layer 302, conductive layer 304, and/or the second insulating layer 308. The titanium nitride layer 312 is formed across the exposed surfaces of substrate 121. In one embodiment, the titanium nitride layer 312 is deposited by a MOCVD process. In one exemplary embodiment described herein, the titanium nitride layer 312 is deposited by a MOCVD process in the process chamber 100 depicted in FIG. 1. Alternatively, the titanium nitride layer 312 may be formed by any suitable CVD process, including a thermal MOCVD process, a plasma-enhanced CVD (PE-CVD) process or the like. In an alternative embodiment, titanium nitride layer 220 may be deposited or formed by an ALD process or a PE-ALD process.

The MOCVD process for depositing the titanium nitride layer 312 includes vaporizing a organic titanium precursor, introducing the vaporized titanium precursor into the CVD chamber 100, maintaining the deposition chamber at a pressure and the substrate 121 at a temperature suitable for the titanium nitride layer 310 to be deposited onto the substrate 121, and thermally decomposing the titanium precursor while depositing titanium nitride layer 312 onto the adhesion layer 310 and the substrate 121.

In one embodiment, the titanium precursor used for the MOCVD process may be a metal-organic compound, such as tetrakis(dialkylamido)titanium compounds, which include tetrakis(dimethylamido)titanium (TDMAT), tetrakis(diethylamido)titanium (TDEAT), tetrakis(ethylmethylamido)titanium (TEMAT), and derivatives thereof. The titanium nitride layer 312 may have a thickness of about 60 Å or less, for example, from about 5 Å to about 50 Å, such as about 50 Å.

During the MOCVD deposition process, several process parameters may be regulated. In one embodiment, the process pressure may be controlled between about 1 Torr to about 10 Torr, for example, about 5 Torr. The substrate temperature may be controlled between about 250 degrees Celsius to about 500 degrees Celsius, such as from about 320 degrees Celsius to about 420 degrees Celsius, for example, about 360 degrees Celsius. The substrate 121 may be exposed to a deposition gas containing the titanium precursor, such as the titanium precursor discussed above, and at least one carrier gas, such as nitrogen, helium, argon, hydrogen, or combinations thereof. In one particular embodiment, the substrate 121 may be exposed to a tetrakis(dialkylamido)titanium compound having a flow rate within a range from about 10 sccm to about 150 sccm, such as about from 20 sccm to about 100 sccm, and for example about 40 sccm to about 70 sccm, for example, about 55 sccm. The deposition gas may further contain at least one carrier gas having a flow rate within a range from about 1,000 sccm to about 5,000 sccm, such as about 2,000 sccm to about 4,000 sccm, for example, about 3,000 sccm. In another embodiment, the substrate 121 is exposed to a deposition gas containing tetrakis(dimethylamido) titanium (TDMAT) with a flow rate of about 55 sccm, nitrogen gas with a flow rate of about 2,500 sccm, and helium with a flow rate of about 600 sccm during the MOCVD process while forming the titanium nitride layer 312.

At step 206, a densifying plasma treatment process is performed on the titanium nitride layer 312 to form a densified titanium nitride layer 314 from the titanium nitride layer 312, as depicted in FIG. 3C. As the titanium nitride layer 312 deposited on the substrate 121 may have undesired elements, such as carbon, oxygen, and the like, other than titanium and nitrogen sourced from the reacting precursors during depositing, the plasma treatment process performed may efficiently drive out and/or eliminate the amount of undesired elements from the resultant titanium nitride layer 312. Removal of the undesired elements from the titanium nitride layer 312 may promote purity and improve the titanium and nitrogen ratio of the densified titanium nitride layer 314. Furthermore, a predetermined stoichiometric ratio range of titanium to nitrogen elements in the densified titanium nitride layer 314 is desired to provide a good nucleation surface for the subsequent conductive layer. Consequently, the titanium nitride layer 312 is treated to form a desired stoichiometric ratio of titanium to nitrogen elements in the densified titanium nitride layer 314 to provide a good nucleation surface for the subsequent conductive layer, thereby successfully enabling the subsequent metallization deposition process. In one embodiment, the titanium nitride layer 312 is treated to be a substantially titanium-rich layer, e.g., stoichiometric ratio of titanium element to nitrogen element of the densified titanium nitride layer 314 greater than 1 (Ti/N>1). As the subsequent layer disposed over the densified titanium nitride layer 314 is typically a conductive metal layer, the densified titanium-rich titanium nitride layer 314 may provide similar metallic material properties that allow the subsequent conductive metal layer to have improved bonding to the densified titanium nitride layer 314.

In one embodiment, the titanium nitride layer 312 may be exposed to the treatment plasma having a plasma power of about less than 500 watts, such as less than 350 watts, for example, about 250 watts. The plasma treatment process may be performed for about 1 seconds to about 60 seconds, for example, from about 1 second to about 40 seconds, and such as from about 2 seconds to about 25 seconds, for example, about 8 seconds. The densified titanium nitride layer 314 may be at least about 15% denser than the titanium nitride layer 312, such as, at least about 20% denser than the titanium nitride layer 312.

During plasma treatment, the titanium nitride layer 312 is exposed to a plasma gas mixture containing at least a nitrogen and a hydrogen gas. Alternatively, an inert gas, such as argon, helium, neon, or combinations thereof, may also be supplied into the plasma gas mixture during the plasma treatment process at step 206. In one embodiment, the nitrogen gas supplied in the plasma gas mixture is controlled at a flow rate greater than the hydrogen gas. As the nitrogen atom has a greater molecular weight than the hydrogen atoms, supplying a higher gas flow rate of nitrogen gas than the hydrogen gas in the plasma gas mixture provides a higher mass ratio of nitrogen in the plasma gas mixture. The higher molecular weight of the nitrogen atoms compared to the hydrogen atoms efficiently assists driving out and reducing the undesired elements, such as carbon or oxygen atoms, from the titanium nitride layer 312, thereby densifying and purifying the titanium nitride layer 312 to form the densified titanium nitride layer 314 with a desirable titanium to nitrogen stoichiometric ratio. Table 1 below depicts the different element percentage contained in the titanium nitride layer 312 and the densified titanium nitride layer 314 prior to and after the plasma treatment process performed at step 206.

TABLE 1
List of element percentage of titanium nitride layer with and without
plasma treatment process

| | Without treatment process | With plasma treatment process |
|---|---|---|
| | (Titanium nitride layer 312) | (Densified titanium nitride layer 314) |
| Ti | 12 | 28 |
| N | 12 | 23 |
| O | >40 | 29 |
| C | 30 | 3.1 |

As depicted in Table 1, prior to the plasma treatment of the titanium nitride layer 312, greater than about 70 percent of the titanium nitride layer 312 is made from the impurities, such as oxygen atoms (>40%) and carbon atoms (about 30%). The titanium to nitrogen stoichiometric ratio is about 1 and the film density is about 3.0 g/cm³. Therefore, prior to the plasma treatment process, the titanium nitride layer 312 has substantially an equal stoichiometric ratio of titanium and nitrogen elements. After the plasma treatment process, the ratios of the impurities, such as oxygen atoms and carbon atoms, contained in the densified titanium nitride layer 314 are greatly reduced from 40 percent to 20 percent for oxygen atoms and from 30 percent to about 3.1 percent for carbon atoms respectively. As a majority of the impurities have been driven out of the titanium nitride layer 312, the resultant densified titanium nitride layer 314 provides a larger ratio of desired elements, titanium and nitrogen as well as providing a desired titanium-rich titanium nitride layer.

Accordingly, by selecting desired process gases during the plasma treatment process, a titanium-rich film, having a stoichiometric ratio of titanium to nitrogen greater than 1 (titanium/nitrogen is 1.2), may be obtained as the titanium-rich titanium nitride layer is believed to provide a good nucleation surface for the subsequent conductive metal layer to nucleate and adhere thereon during the subsequent deposition process. Furthermore, the film density is also increased from about 3.0 g/cm³ to about 3.8 g/cm³, resulting in improved film sheet resistance and contact resistance. In one embodiment, the substrate 121 may be exposed to the plasma gas having a nitrogen gas rate between about 400 sccm and about 4800 sccm and a hydrogen gas rate between about 50 sccm and about 600 sccm. In another embodiment, the nitrogen and the hydrogen gas supplied in the plasma gas mixture is controlled at a flow ratio between about 20:1 and about 3:1, such as between about 15:1 and about 5:1, for example about 8:1. In one particular embodiment, the nitrogen gas flow is controlled at about 2400 sccm and the hydrogen gas is controlled at about 300 sccm.

In another embodiment, the titanium nitride layer 312 and the densified titanium nitride layer 314 may be formed by incremental steps (e.g., multiple steps), instead of a one step deposition and plasma treatment process. The steps 204, 206 may be performed repeatedly, as indicated by loop 208, to incrementally deposit and plasma densify a stack of titanium nitride layers until a desired total stack thickness is reached. For example, as an initial step of titanium nitride layer deposition process performed at step 204, only an initial portion of the total desired titanium nitride layer thickness 312 is formed on the substrate 121. Subsequently, the densification process is performed to plasma treat the initial portion of the titanium nitride layer 312 to an initial densified titanium nitride layer 314. The steps of 204 and 206 are repeated to gradually increase the thickness of the titanium nitride layer and incrementally drive out impurities formed in each deposition cycle of the titanium nitride layer. The incremental deposition and densification cycle continues until the titanium nitride layer 312 has achieved a desired thickness density and stoichiometric ratio between titanium and nitrogen. It is believed that the incremental deposition and densification of the titanium nitride layer can efficiently reduce and maintain the titanium nitride layer at a desired film resistivity. By gradual deposition and densification, the titanium and nitrogen atoms of the titanium nitride layer may be more densely packed and the impurities may be timely driven out of the film structure prior to a next layer of titanium and nitrogen atoms being disposed thereover. Accordingly, the resistivity of the titanium nitride layer may be preserved and controlled.

In an exemplary embodiment, the deposition process 204 and the densification process 206 may be repeatedly performed multiple times. In the first cycle, as discussed above, the titanium nitride layer 312 with a desired thickness, as depicted in FIG. 3B, and the densified titanium nitride layer 314, as depicted in FIG. 3C may be obtained after the first cycle. In the following second cycle, a second titanium nitride layer 312a with a desired thickness is deposited, as depicted in FIG. 3C1, and then plasma treated to form a densified second titanium nitride layer 314a, as depicted in FIG. 3C2. The deposition process 204 and the densification process 206 are then repeated until a desired thickness is reached to form a titanium nitride stack with densified titanium nitride layers. Although only two densified titanium nitride layer 314a, 314b are shown in FIGS. 3C2, it is contemplated that the processes 204 and 206 may be repeated for three, four or even more times. The diffusion potential of the titanium nitride barrier stack (e.g., metal diffusion potential) may be calculated to quantitatively determine the effectiveness of the barrier layers. The diffusion potential may be used to determine a desired thickness of each densified titanium nitride layer formed during steps 204 and 206 to determine how many densified titanium nitride layers should be deposited at steps 204 and 206. In one embodiment, in each deposition cycle, the thickness of the titanium nitride layer 312 is controlled at between about 10 Å and about 20 Å, and the desired total thickness of the densified titanium nitride layer 314 after densification is between about 30 Å and about 60 Å. In one embodiment, the densified titanium nitride layer 314 comprises at least four incrementally deposited densified layers.

The deposition process of step 204 and the densification process of step 206 may be performed in a single chamber, or in different chambers for different process requirements. In one embodiment, the deposition process of step 204 and the densification process of step 206 are performed in a single chamber.

After densification, the densified titanium nitride layer 314 may be subjected to an air exposure process to expose the densified titanium nitride layer 314 to air prior to deposition of the subsequent layers. The air exposure process incorporates oxygen elements from the adjacent environment into the densified titanium nitride layer 314, forming titanium oxygen (Ti—O) bonds. As the Ti—O bonds have a slightly higher free energy, the Ti—O bonds tend to limit the presence of nitrogen on the upper surface of the densified titanium nitride layer 314. It is believed that excess Ti—N bonds on the upper surface of the densified TiN layer may retard or limit the nucleation of the subsequently deposited materials. Accordingly, exposing the densified titanium nitride layer 314 to the air for oxygen incorporation can provide a better nucleation surface of the subsequent to-be deposited layer and also, the barrier properties of the densified titanium nitride layer 314 can be improved. In one embodiment, the densified titanium nitride layer 314 may be exposed to air for less than about 24 hours. In another embodiment, the densified titanium nitride layer 314 may be exposed to air between about 30 minutes and about 8 hours. In yet another embodiment, the densified titanium nitride layer 314 may be exposed to air for about 1 hour.

After the densified titanium nitride layer 314 is formed on the substrate 121 and the air exposure process is completed, a conductive metal layer 316, as depicted in FIG. 3D, is formed over the densified titanium nitride layer 314, filling the via 306 to form a metal interconnection structure on the substrate 121. The conductive metal layer 316 may be a seed layer, a nucleation, a bulk layer, a fill layer, or other suitable conductive metal layer that may be used to form an interconnect. In one embodiment, the conductive metal layer 316 may be an aluminum layer, such as aluminum or aluminum alloy, fabricated by a CVD process, such as an iFill® process, commercially available from Applied Material Inc., Santa Clara, Calif. The CVD-aluminum deposition process provides conformal step coverage, reduced overhang, enhanced bottom-up filling capability so that while depositing, the aluminum layer may be mainly nucleated from the bottom of the via 306, providing selective deposition from the via bottom 324 and the exposed outer surface 322 out of the via 306, thereby efficiently reducing overhang or other associated defects.

In another embodiment, the conductive metal layer 316 may contain a conductive metallic material, such as copper, titanium, tungsten, aluminum, tantalum, ruthenium, cobalt, alloys thereof, or combinations thereof. The conductive metal layer 316 may be deposited or formed by a PVD process, an ALD process, a CVD process, an electrochemical plating (ECP) process, or an electroless deposition process.

Thus, methods for forming and densifying a titanium nitride layer are provided. The method produces a low resistivity titanium nitride layer while providing a good nucleation surface for the subsequent conductive metal layer to be deposited thereover, thereby providing a good adhesion between the deposition interfaces and improving interconnection electrical properties.

While the foregoing is directed to embodiments of the invention, other and further embodiments of the invention may be devised without departing from the basic scope thereof, and the scope thereof is determined by the claims that follow.

What is claimed is:

1. A method for forming a titanium nitride layer on a substrate, comprising:
depositing a titanium nitride layer on the substrate by a metal-organic chemical vapor deposition process; and
performing a plasma treatment process on the deposited titanium nitride layer, wherein the plasma treatment process operates to density the deposited titanium nitride layer, resulting in a densified titanium nitride layer, wherein the plasma treatment process further comprises:
supplying a plasma gas mixture containing a nitrogen gas to hydrogen gas ratio between about 20:1 and about 3:1; and
applying less than about 500 Watts RF power to the plasma gas mixture.

2. The method of claim 1, further comprising:
repeating steps of depositing process and the plasma treatment process.

3. The method of claim 1, wherein the depositing process and the plasma treatment process are repeated until a total thickness of the densified titanium nitride layers is between about 40 Å and about 60 Å.

4. The method of claim 1, wherein the plasma treatment process is performed for a time period between about 1 seconds and about 40 seconds.

5. The method of claim 1, wherein applying less than 500 Watts RF power further comprises:
applying about 250 Watts RF power.

6. The method of claim 1 further comprising:
forming a conductive layer on the densified titanium nitride layer by a CVD process.

7. The method of claim 6, wherein the conductive layer is an aluminum layer.

8. The method of claim 6 further comprising:
exposing the densified titanium nitride layer to air prior to forming the conductive layer thereover.

9. The method of claim 1, wherein the densified titanium nitride layer has a titanium stoichiometric ratio greater than nitrogen stoichiometric ratio.

10. The method of claim 1, wherein the densified titanium nitride layer has a stoichiometric ratio of titanium to nitrogen greater than 1.

11 A method for forming a titanium nitride layer on a substrate, comprising:
depositing a first titanium nitride layer to a thickness of between about 10 Å and about 20 Å by a first metal-organic chemical vapor deposition process;
plasma treating the first titanium nitride layer by applying less than about 500 Watts RF power to a plasma gas mixture comprising nitrogen gas and hydrogen gas;
depositing a second titanium nitride layer to a thickness of between about 10 Å and about 20 Å on the first titanium nitride layer; and
plasma treating the second titanium nitride layer deposited on the substrate by applying less than about 500 Watts RF power to a plasma gas mixture comprising nitrogen gas and hydrogen gas.

12. The method of claim 11, further comprising:
depositing a third titanium nitride layer to a thickness of between about 10 Å and about 20 Å on the second titanium nitride layer;
plasma treating the third titanium nitride layer deposited on the substrate by applying less than about 500 Watts RF power to a plasma gas mixture comprising nitrogen gas and hydrogen gas;
depositing a fourth titanium nitride layer to a thickness of between about 10 Å and about 20 Å on the third titanium nitride layer; and
plasma treating the fourth titanium nitride layer deposited on the substrate by applying less than about 500 Watts RF power to a plasma gas mixture comprising nitrogen gas and hydrogen gas, wherein the first, second, third and the fourth titanium nitride layer forms a bulk treated titanium nitride layer.

13. The method of claim 12, wherein the bulk treated titanium nitride layer has a titanium stoichiometric ratio greater than nitrogen stoichiometric ratio.

14. The method of claim 12, wherein the bulk treated titanium nitride layer has a stoichiometric ratio of titanium to nitrogen about 1.2:1.

15. The method of claim 12, further comprising:
exposing the bulk treated titanium nitride layer to air for between about 30 minutes and about 8 hours.

16 A method for forming a titanium nitride layer on a substrate, comprising:
providing a substrate having vias formed in an insulating layer disposed on a substrate, wherein the substrate has a titanium layer disposed on the insulating layer and filling a portion of the vias formed therein; and
exposing the substrate sequentially to a titanium nitride deposition gas and to a densifying plasma to form a plurality of densified titanium nitride barrier layers, wherein each of the densified titanium nitride barrier layers has a thickness of about 20 Å or less, and wherein the densifying plasma is formed by:
supplying a plasma gas mixture containing a nitrogen gas to hydrogen gas ratio between about 20:1 and about 3:1; and
applying a less than about 500 Watts RF power to the plasma gas mixture.

17. The method of claim 16, wherein the substrate is sequentially exposed to the titanium nitride deposition gas and to the densifying plasma during a deposition-densification cycle.

18. The method of claim 17, wherein the deposition-densification cycle is performed at least four times.

19. The method of claim 17, further comprising:
exposing the substrate to air between about 30 minutes and about 8 hours.

20. The method of claim 19 further comprising:
incorporating oxygen elements into the densified titanium nitride layer.

21. The method of claim 16, further comprising:
filling the via with a CVD deposited aluminum layer.

22. The method of claim 16, wherein the plurality of densified titanium nitride barrier layers have a titanium element ratio greater than nitrogen element ratio.

23. The method of claim 16, wherein the plurality of densified titanium nitride barrier layers have a ratio of titanium to nitrogen about 1.2:1.
